(19) United States
(12) Patent Application Publication
(10) Pub. No.: US 2023/0290812 A1
(43) Pub. Date: Sep. 14, 2023

(54) DOPED METAL-INSULATOR-METAL (MIM) CAPACITOR OF A MEMORY ARRAY

(71) Applicant: Intel Corporation, Santa Clara, CA (US)

(72) Inventors: Travis Lajoie, Forest Grove, OR (US); Andre Baran, Portland, OR (US); Alexandra De Denko, Saint Helens, OR (US); Christine Radlinger, Portland, OR (US); Yu-Che Chiu, Hillsboro, OR (US); Yixiong Zheng, Hillsboro, OR (US)

(73) Assignee: Intel Corporation, Santa Clara, CA (US)

(21) Appl. No.: 17/654,530

(22) Filed: Mar. 11, 2022

(51) Int. Cl. H01L 49/02; H01L 27/108

(52) U.S. Cl. CPC H01L 28/60; H01L 27/10808

(57) ABSTRACT

An integrated circuit (IC) includes a transistor, and a first layer including electrically conductive material. In an example, the first layer is conductively coupled to the transistor. The IC further includes a second layer including electrically conductive material above the first layer. The IC further includes one or more intervening layers between the first and second layers. In an example, the one or more intervening layers include at least a third layer, wherein the third layer includes (i) a first metal, (ii) oxygen, and (iii) one or both of a second metal or an oxide thereof within the third layer. In an example, the first layer, the second layer, and the one or more intervening layers form a metal-insulator-metal (MIM) capacitor. In an example, the MIM capacitor and the transistor, in combination, form a memory cell of a dynamic random access memory (DRAM) array.

### FIELD OF THE DISCLOSURE

The present disclosure relates to integrated circuits, and more particularly, to capacitors such as those used in memory cells.

### BACKGROUND

In some semiconductor memory devices, such as DRAMs (Dynamic Random Access Memory), each memory cell comprises a transistor and a capacitor. For example, a memory cell uses a corresponding capacitor to store a bit of information and a corresponding transistor to access that stored bit. Some DRAM devices use Metal-Insulator-Metal or MIM capacitors. There remain non-trivial challenges with such capacitors.

### BRIEF DESCRIPTION OF THE DRAWINGS

FIG. 1 illustrates a cross-sectional view of a section of an integrated circuit (IC) comprising a first metal-insulator-metal (MIM) capacitor and a second MIM capacitor, where each of the first and second capacitors comprise (i) a first electrode, (ii) a second electrode, and (iii) one or more intervening layers between the first and second electrodes, wherein the one or more intervening layers comprise at least one layer comprising (a) a first metal, (b) oxygen, and (c) one or both of a second metal or an oxide thereof doped within that one layer, wherein the second metal is elementally different from the first metal, in accordance with an embodiment of the present disclosure.

FIG. 2 illustrates the IC of FIG. 1, with discontinuity between a first section of the one or more intervening layers of the first capacitor and a second section of the one or more intervening layers of the second capacitor, in accordance with an embodiment of the present disclosure.

FIG. 3 illustrates the first and second capacitors of FIG. 1 in conjunction with a first transistor and a second transistor, respectively, to respectively form a first memory cell and a second memory cell of a DRAM array, in accordance with an embodiment of the present disclosure.

FIG. 4 illustrates a flowchart depicting a method of forming an IC (such as the IC of FIGS. 1 and 3) comprising first and second MIM capacitors respectively above corresponding first and second transistors, where each of the first and second capacitors comprise (i) a first electrode, (ii) a second electrode, and (iii) one or more intervening layers between the first and second electrodes, wherein the one or more intervening layers comprise at least a first layer comprising (a) a first metal, (b) oxygen, and (c) one or both of a second metal or an oxide thereof doped within the first layer, in accordance with an embodiment of the present disclosure.

FIGS. 5A-5F illustrate cross-sectional views of an IC (such as the IC of FIG. 1) in various stages of processing, in accordance with an embodiment of the present disclosure.

FIG. 6 illustrates a computing system implemented with integrated circuit structures having one or more memory cells formed using the techniques disclosed herein, in accordance with some embodiments of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles (e.g., curved or tapered sidewalls and round corners), and some features may have surface topography or otherwise be non-smooth, given real-world limitations of fabrication processes. Further still, some of the features in the drawings may include a patterned and/or shaded fill, which is merely provided to assist in visually identifying the different features. In short, the figures are provided merely to show example structures.

### DETAILED DESCRIPTION

Provided herein are techniques for forming capacitors, such as those that can be used in memory cells. The techniques are particularly well-suited, for instance, for forming capacitors of memory cells in an interconnect structure during backend of line (BEOL) processing of an integrated circuit, although other capacitor applications will be apparent. An example embodiment is a memory array comprising a plurality of memory cells, wherein individual memory cells include a transistor and a metal-insulator-metal (MIM) capacitor, and wherein one or more metal oxide layers of a MIM capacitor is doped with a metal or an oxide thereof. In one embodiment, an integrated circuit (IC) includes a transistor, and a first layer including electrically conductive material. In an example, the first layer is conductively coupled to a terminal of the transistor. The IC further includes a second layer including electrically conductive material above the first layer. The IC further includes one or more intervening layers between the first and second layers. In an example, the one or more intervening layers include at least a third layer, wherein the third layer includes (i) a first metal, (ii) oxygen, and (iii) one or both of a second metal or an oxide thereof doped within the third layer. In an example, the first layer, the second layer, and the one or more intervening layers form a metal-insulator-metal (MIM) capacitor. In an example, the MIM capacitor and the transistor, in combination, form, or are otherwise part of, a memory cell of a dynamic random access memory (DRAM) array.

In another embodiment, a memory array comprises a memory cell comprising (i) a transistor, and (ii) a capacitor above and conductively coupled to a terminal of the transistor. In an example, the capacitor comprises a first electrode, a second electrode, and one or more layers of metal oxide between the first and second electrodes. In an example, at least a one layer of the one or more layers of metal oxide comprises (i) an oxide of a first metal, and (ii) a second metal or an oxide thereof doped within that one layer.

In another embodiment, a capacitor structure comprises a first electrode comprising conductive material, a second electrode comprising conductive material, and a first layer, a second layer, and a third layer between the first and second electrodes. In an example, the first layer comprises an oxide of a first metal, the second layer comprise an oxide of a second metal, and the third layer comprises an oxide of a third metal. In an example, at least one of the first, second, or third layers is doped with one or both of (i) a fourth metal or (ii) an oxide of the fourth metal. In an example, the capacitor structure is coupled to a drain terminal of a transistor, and the capacitor structure and the transistor form, or are otherwise part of, a DRAM memory cell. Numerous variations, embodiments, and applications will be apparent in light of the present disclosure.

### General Overview

As previously noted, memory cells include a corresponding transistor and a corresponding capacitor coupled to the transistor, where the capacitor stores a bit of information and the transistor allows for writing and reading that bit. For example, the capacitor can either be charged or discharged and these two states are used to represent two possible values of 0 or 1 of a bit. Metal-insulator-metal (MIM) capacitors, with an insulator layer between two conductive electrodes, are sometimes used in memory cells. As also previously noted above, there remain a number of non-trivial challenges with such capacitors. For instance, in the case of some memory cells, such as DRAM cells, the electric charge on the capacitor gradually leaks, which results in loss of the charge in the capacitor. To prevent this, a DRAM memory cell is periodically refreshed, which involves periodically rewriting the data in the capacitor, to restore the capacitor to an appropriate charge. To this end, and as will be appreciated in light of this disclosure, it may be desirable to tune characteristics of various materials of the capacitors, which in turn control characteristics (e.g., capacitance, leakage current, and/or one or more other characteristics) of the capacitor.

Accordingly, techniques are provided herein to form MIM capacitors of a memory array (such as a DRAM memory array), wherein one or more dielectric layers comprising metal oxides are used for the insulator or ‘I’ portion of a MIM capacitor structure, and wherein at least one of the one or more metal oxide layers is doped with metal or an oxide thereof, to help control characteristics of the MIM capacitor of the memory cell.

In one embodiment, a capacitor has a lower electrode comprising a metal or an alloy thereof, and an upper electrode comprising a metal or an alloy thereof. In an example memory cell application, the lower electrode of the capacitor is coupled to a drain terminal of a corresponding transistor, where the transistor and the capacitor in combination form, or are otherwise part of, the memory cell. In one embodiment, the upper and lower electrodes may include any suitable electrically conductive material, such as copper, silver, aluminum, tantalum, aluminum, tungsten, ruthenium, nickel, platinum, molybdenum, manganese, or an alloy thereof such as titanium nitride, tantalum nitride, titanium aluminum nitride, molybdenum oxide, manganese oxide, tungsten oxide, or another appropriate conductive material.

In an example, one or more layers of dielectric material, such as one or more metal oxide layers, are between the upper and lower electrodes of a capacitor of a memory cell. Merely as an example, there may be one layer, two layers, three layers, or a higher number of intervening dielectric layers between the upper and lower electrodes. In some examples, three such layers are present between the upper and lower electrodes, although other embodiments may have one or two such layers, or more than three layers, as will be appreciated in light of this disclosure. In an example where there are three or more such layers in a stack, two such layers on the two ends of the stack can act as passivation layers, with one or more middle layers between the two passivation layers.

For example, each of the intervening layers between the upper and lower electrodes can include an oxide of hafnium, aluminum, zirconium, titanium, tantalum, or another appropriate metal. In one specific example case that has three intervening dielectric layers between the upper and lower electrodes, the two end layers comprise titanium oxide, and the middle layer comprises zirconium oxide. In another such example, the two end layers comprise aluminum oxide, and the middle layer comprises hafnium oxide. Other dielectric material combinations will be appreciated in light of this disclosure.

In one embodiment, at least one of the intervening layers between the upper and lower electrodes is doped. In an example, exactly one of the intervening layers is doped. In another example, more than one, but not all, of the intervening layers may be doped. For example, assuming a first, a second, and a third layer between the upper and lower electrodes, if the first layer is doped, then the second and/or third layers remain substantially undoped, where substantially undoped implies a doping concentration of impurity that is less than 1E12 (e.g., less than 1E10) atoms per cubic cm, for example. An appropriate doping concentration may be used for doping one or more of the intervening layers. For example, doping one or more of the intervening layers may include forming impurity dopants (e.g., a metal or an oxide of the metal, a discussed herein) in the material in concentrations defined by a range of 1E12 to 1E24 (e.g., 1E15 to 1E21) atoms per cubic cm, or other suitable dopant amount, as will be apparent in light of this disclosure.

For example, at least one of the intervening layers is doped with an appropriate metal, such as hafnium, aluminum, zirconium, titanium, lanthanum, yttrium, gadolinium, palladium, and/or another appropriate metal, and/or oxides of one or more of these metals. In an example, if an intervening layer comprises an oxide of a first metal and is doped, then the dopant comprises one or more second metals and/or oxides of the one or more second metals, where the one or more second metals are elementally different from the first metal. For example, if a layer comprises titanium oxide and is doped, then the dopant may comprise any of hafnium, aluminum, zirconium, lanthanum, yttrium, gadolinium, palladium, and/or oxides thereof, but the dopant may not include titanium or its oxide.

In one embodiment, doping one or more of the intervening layers between the upper and lower electrodes may be performed using any suitable doping process, such as in situ doping, diffusion-based doping, ion implantation, or another appropriate doping process. For example, during formation of the capacitor, the lower electrode is formed, and then one or more intervening metal oxide layers are deposited (e.g., conformally deposited) above the lower electrode. In an example, during (in situ) or subsequent (implantation or diffusion) to deposition of an intervening metal oxide layer, the intervening metal oxide layer is doped with impurity using any suitable doping process. Subsequently, the upper electrode is formed over the intervening metal oxide layer.

In an example, doping an intervening oxide layer of a MIM capacitor of a memory cell may allow tuning a bandgap, crystallinity, and/or dielectric constant of the intervening layers between the upper and lower electrodes. In one embodiment, appropriately doping one or more of the intervening layers facilitates fine tuning one or more characteristics (e.g., bandgap, crystallinity, and/or dielectric constant) of these layers, which is turn facilitates fine tuning one or more characteristics (e.g., capacitance, leakage current, or one or more other characteristics) of the capacitor, which then in turn improves performance of memory cell comprising the capacitor. For example, appropriately doping one or more of the intervening layers facilitates tuning the capacitance of the capacitors based on one or more characteristics of the transistors of the memory cells, to improve overall performance of the memory cells.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools may be used to detect a MIM capacitor of a memory cell with a first electrode, a second electrode, and one or more intervening metal oxide layers between the first and second electrodes, wherein at least one of the intervening metal oxide layers comprises an oxide of a first metal, and the at least one of the intervening metal oxide layers is doped with a second metal or an oxide thereof, where the second metal is elementally different from the first metal. Numerous configurations and variations will be apparent in light of this disclosure.

### Architecture and Methodology

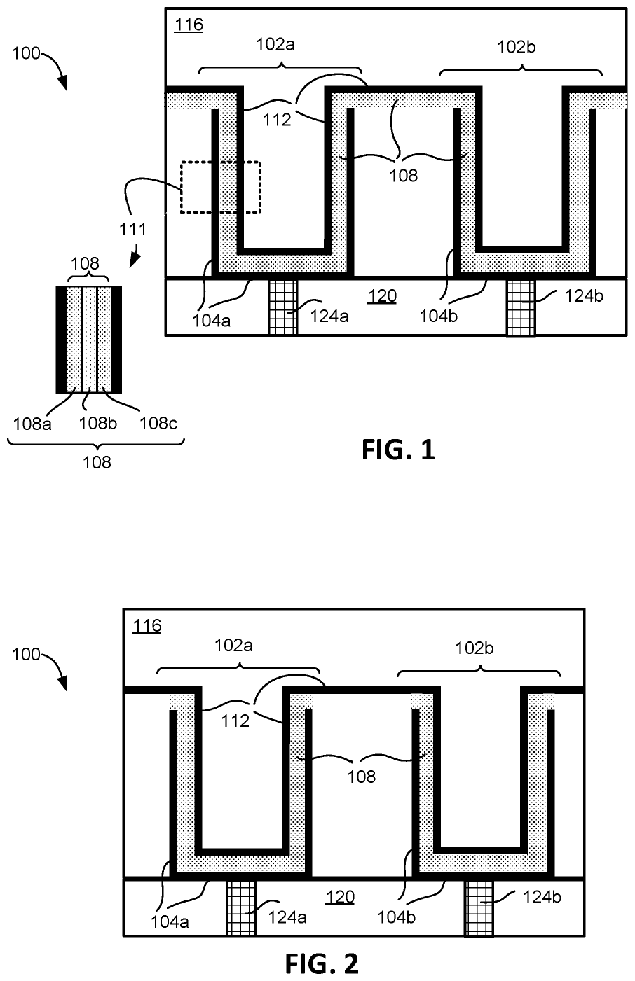

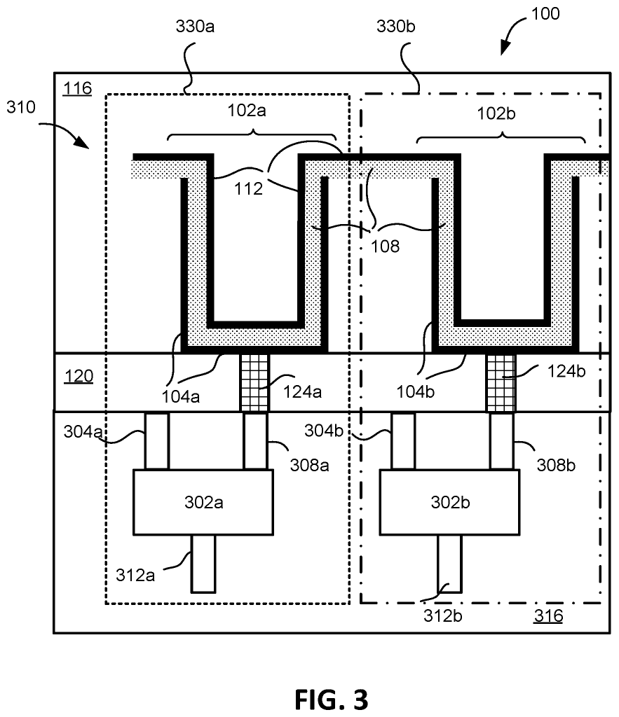

FIG. 1 illustrates a cross-sectional view of a section of an integrated circuit (IC) 100 comprising a first metal-insulator-metal (MIM) capacitor 102a and a second MIM capacitor 102b, where each of the first and second capacitors 102a, 102b comprise (i) a first electrode 104, (ii) a second electrode 112, and (iii) one or more intervening layers 108 between the first and second electrodes, wherein the one or more intervening layers 108 comprise at least a first layer comprising (a) a first metal, (b) oxygen, and (c) one or both of a second metal or an oxide thereof doped within the first layer, wherein the second metal is elementally different from the first metal, in accordance with an embodiment of the present disclosure. Two example capacitors 102a, 102b are illustrated in FIG. 1, although the IC 100 may include several such capacitors. As will be discussed herein later (e.g., with respect to FIG. 3), each capacitor 102 is conductively coupled to a corresponding transistor, to form a corresponding memory cell, such as a DMA memory cell.

As illustrated in FIG. 1, the capacitor 102a comprises the electrode 104a and the capacitor 102b comprises the electrode 104b. The electrode 112 is common to both the capacitors. For example, a first section of the electrode 112 is within the capacitor 102a, and a second section of the electrode 112 is within the capacitor 102b, and the first and second sections are the electrode 112 are conjoined or conductively coupled.

In each capacitor 102a, 102b, the electrode 112 is above the corresponding electrode 104. Accordingly, the electrodes 104a, 104b are also referred to herein as lower electrodes 104a, 104b, respectively, due to their positions relative to the electrode 112. The electrode 112 is referred to herein as an upper electrode 112, due to its position relative to the electrodes 104a, 104b.

In the example of FIG. 1, each of the lower electrodes 104a, 104b of the capacitors 102a, 102b, respectively, has a shape that resembles the letter “U,” e.g., has a cup-like shape. However, in other examples, the lower electrodes 104a, 104b can have another appropriate shape.

The upper electrode 112 of the two capacitors 102a, 102b are conductively coupled, to form a common upper electrode. For example, a section of the upper electrode 112 within the capacitor 102a has an “U” shape, and another section of the upper electrode 112 within the capacitor 102b also has the “U” shape, and the upper electrode 112 further comprises a section that conjoins and conductively couples the two U-shaped sections.

In one embodiment, the electrodes 104a, 104b, 112 may include any suitable electrically conductive material, such as a metal or metal alloy material including, e.g., copper, silver, aluminum, tantalum (Ta), aluminum (Al), tungsten (W), nickel (Ni), platinum (Pt), molybdenum (Mo), manganese (Mn), or an alloy thereof, titanium nitride (TiN), tantalum nitride (TaN), titanium aluminum nitride (TiAlN), molybdenum oxide (MoO2), manganese oxide (MnO2), tungsten oxide (WO2), or another appropriate conductive material. In one embodiment, one or both the electrodes 104a, 104b may include a multilayer structure including two or more material layers, for example. In some embodiments, the electrode 112 may include a multilayer structure including two or more material layers, for example. In one embodiment, the electrodes 104a, 104b, 112 may have any suitable thickness, such as a thickness in the range of 10 to 500 nm (e.g., 50 to 300 nm), or any other suitable range, as will be appreciated in light of this disclosure.

In one embodiment, the capacitors 102a, 102b are embedded within an Interlayer Dielectric (ILD) material 116. The ILD 116 may be an appropriate dielectric material, such as a low-K dielectric material, silicon dioxide, or another appropriate dielectric material.

In one embodiment, the IC 100 comprises a contact 124a that couples the electrode 104a of the capacitor 102a to a corresponding semiconductor component (such as a transistor below the capacitor 102a, see FIG. 3), and also comprises a contact 124b that couples the electrode 104b of the capacitor 102b to a corresponding semiconductor component (such as another transistor below the capacitor 102b, see FIG. 3). The contacts 124a, 124b may represent vias, or metal wirings, or an appropriate contact structure formed between the bottom of the corresponding capacitor 102 and a semiconductor component. The contacts 124a, 124b comprise conductive material, such as copper, ruthenium, molybdenum, tungsten, aluminum, and/or an alloy or compound thereof.

In one embodiment, the contacts 124a, 124b are embedded within an ILD material 120. The ILD 120 may be an appropriate dielectric material, such as a low-K dielectric material, silicon dioxide, or another appropriate dielectric material. The ILD 120 may be same as the ILD material 116 or may be different. In an example and although not illustrated, an etch stop layer may be present between the ILD 116 and ILD 120, although there may not be any such etch stop layer in another example.

In one embodiment, one or more layers 108 is between the upper electrode 112 and the lower electrodes 104a, 104b. The layers 108 are present between the electrodes 104a and 112, and also between the electrodes 104b and 112. For example, a section of the layers 108 within the capacitor 102a (e.g., between the electrodes 104a and 112) has an “U” shape, and another section of the layers 108 within the capacitor 102b (e.g., between the electrodes 104b and 112) also has the “U” shape, and the layers 108 further comprises a section that conjoins and couples the two U-shaped sections of the two capacitors. This results in continuous presence of the layers 108 between the capacitors 102a, 102b. That is, there is no discontinuity between a section of the layers 108 within the capacitor 102a and another section of the layers 108 within the capacitor 102b.

Note that although FIG. 1 illustrates the layers 108 within the two capacitors 102a, 102b to be continuous, the layers 108 within the two capacitors 102a, 102b may not be continuous. For example, FIG. 2 illustrates the IC of FIG. 1, with discontinuity between a first section of the one or more intervening layers 108 of the capacitor 102a and a second section of the one or more intervening layers 108 of the capacitor 102b, in accordance with an embodiment of the present disclosure. Thus, in FIG. 2, a section of the layers 108 within the capacitor 102a (e.g., between the electrodes 104a and 112) has the “U” shape, and another section of the layers 108 within the capacitor 102b (e.g., between the electrodes 104b and 112) also has the “U” shape, and the two U-shaped sections are not conjoined or coupled. This results in discontinuity between the section of the layers 108 within the capacitor 102a and another section of the layers 108 within the capacitor 102b. Other than the discontinuity in the layers 108 in FIG. 2, the IC of FIG. 2 is similar to the IC of FIG. 1.

Referring again to FIG. 1, illustrated is a magnified view of a portion 111 of the layers 108. In the example of FIG. 1, the layers 108 comprise three distinct and/or compositionally different layers 108a, 108b, 108c. Although three layers 108a, 108b, and 108c are illustrated, in an example, the layers 108 may comprise any different number of layers, such as one, two, four, or higher.

In one embodiment, each of the layers 108a, 108b, 108c comprise dielectric or insulating material. The layers 108 form the “I” part of the MIM (metal-insulator-metal) capacitors 102a, 102b. In an example, the layer 108a is compositionally different from the layer 108b, and the layer 108b is compositionally different from the layer 108c. Note that in an example, the layers 108a and 108c may be compositionally similar, and in such an example, each of the layers 108a, 108c maybe compositionally different from the layer 108b. In an example, at least one of the layers 108a, 108b, 108c comprise high-K dielectric material, and at least another of the layers 108a, 108b, 108c may comprise low-K dielectric material. In another example, each of the layers 108a, 108b, 108c may comprise high-K dielectric material.

In one embodiment, each of the layers 108a, 108b, 108c comprise a thin film of one or more metal oxides. For example, each of the layers 108a, 108b, 108c can include an oxide of hafnium (Hf), aluminum (Al), zirconium (Zr), titanium (Ti), tantalum (Ta), or another appropriate metal. Merely as an example, the layers 108a and 108c may comprise titanium oxide, whereas the layer 108b may comprise zirconium oxide. In another example, the layers 108a and 108c may comprise aluminum oxide, whereas the layer 108b may comprise hafnium oxide. Other combinations may also be possible.

In some examples where the layers 108 comprise three layers, the layers 108a and 108c on two ends act as passivation layers, with the layer 108b between the two passivation layers 108a and 108c. In some such examples, the layers 108a and 108c on two ends are substantially compositionally similar (e.g., have oxide of the same metal) and have the same band gap and the same dielectric constant. In some such examples, the layers 108a and 108c on two ends have a greater thickness than a thickness of the middle layer 108b.

In one embodiment, each of the layers 108a, 108b, 108c are conformal layers. In an example, each of the layers 108a, 108c has a thickness in the range of 0.5-100 nm (e.g., 2-40 nm). In an example, a thickness of the layer 108b is at least twice, or at least thrice, or at least 4× the thickness of any of the layers 108a, 108c. In an example, a total thickness of the layers 108 is in the range of 2-300 nm (e.g., 6-120 nm).

In one embodiment, at least one of the layers 108a, 108b, 108c is doped. In an example, exactly one of the layers 108a, 108b, 108c comprise an appropriate dopant. In another example, more than one, but not all, of the layers 108a, 108b, 108c may be doped. For example, if layer 108a is doped, layers 108b and/or 108c remain substantially undoped, where substantially undoped implies a doping concentration of impurity that is less than 1E12 (e.g., less than 1E10) atoms per cubic cm, for example. In another example, if layer 108b is doped, layers 108a and/or 108c remain substantially undoped; and if layer 108c is doped, layers 108a and/or 108b remain substantially undoped.

An appropriate doping concentration may be used for doping one or more of the layers 108a, 108b, 108c. For example, doping one or more of the layers 108a, 108b, 108c may include forming impurity dopants (e.g., a metal or an oxide of the metal, discussed herein below) in the material in concentrations defined by a range of 1E12 to 1E24 (e.g., 1E15 to 1E21) atoms per cubic cm, or any other suitable minimum or maximum threshold dopant amount, as will be apparent in light of this disclosure. For example, at least one of the layers 108a, 108b, 108c is doped with an appropriate metal, such as hafnium, aluminum, zirconium, titanium, lanthanum (La), yttrium (Y), gadolinium (Gd), palladium (Pd), and/or another appropriate metal, and/or oxides of one or more of these metals.

In an example, if a layer 108x (where x can be a, b, or c in the example of FIG. 1) comprise an oxide of a first metal and is doped, then the dopant comprises one or more second metals and/or oxides of the one or more second metals, where the second metals are elementally different from the first metal. For example, if a layer 108x (which can be any of 108a, 108b, 108c) comprises titanium oxide and is doped, then the dopant may comprise any of hafnium, aluminum, zirconium, lanthanum, yttrium, gadolinium, palladium, and/or oxides thereof, but the dopant may not include titanium or its oxide.

In an example, doping heterogenous elements within an oxide layer 108 may allow tuning a bandgap, crystallinity, and/or dielectric constant of the layer 108. In one embodiment, appropriately doping one or more of the layers 108a, 108b, 108c facilitates fine tuning one or more characteristics (e.g., bandgap, crystallinity, and/or dielectric constant) of these layers, which is turn facilitates fine tuning one or more characteristics (e.g., capacitance, leakage current, or one or more other characteristics) of the capacitors 102a, 102b, which then in turn improves performance of memory cells comprising the capacitors. For example, appropriately doping one or more of the layers 108a, 108b, 108c facilitates tuning the capacitance of the capacitors 102a, 102b, based on one or more characteristics of the transistors 302a, 302b (see FIG. 3 herein later), to improve overall performance of the memory cells 330a, 330b (again, see FIG. 3 herein later).

FIG. 3 illustrates the first and second capacitors 102a, 102b of FIG. 1 in conjunction with a first transistor 302a and a second transistor 302b, respectively, to respectively form a first memory cell 330a and a second memory cell 330b of a DRAM array 310, in accordance with an embodiment of the present disclosure. For example, individual DRAM memory cells 330 comprises a capacitor 102 and a transistor 302. A memory cell 330 uses the capacitor 102 to store a bit of information. Although the DRAM array 310 includes various other components (such as sense amplifier, word line selection circuit, bit line selection circuit, and/or other components for operation of the DRAM array), such components are not illustrated or discussed herein in detail, so as to not obfuscate the principles of this disclosure.

In FIG. 3, the internal structures of individual transistors are not illustrated, and the transistors 302a, 302b are illustrated symbolically as a black box. In an example, the transistors 302 are in a gate-bottom configuration, where the source and drain terminals are above the transistor, and the gate terminal is below the transistor. Each transistor 302 comprises a source contact 304 coupled to a corresponding bit line (not illustrated), and a drain contact 308 coupled to the lower electrode 104 of the corresponding capacitor 102 through the connector 124. For example, transistor 302a comprises a source contact 304a coupled to a corresponding bit line, and a drain contact 308a coupled to the lower electrode 104a of the corresponding capacitor 102a through the connector 124a. Similarly, transistor 302b comprises a source contact 304b coupled to a corresponding bit line, and a drain contact 308b coupled to the lower electrode 104b of the corresponding capacitor 102b through the connector 124b.

In an example, the transistors 302a, 302b are formed within an ILD 316, which may be same as, or different from, the ILDs 120 and/or 116. Although not illustrated, in an example, an etch stop layer may be present between the ILD 120 and 316. In some other examples, no such etch stop layer may be present between the ILD 120 and 316, e.g., depending upon a process used to form the transistors 302 and the contacts 124.

As illustrated, the capacitor 102a and the transistor 302a form, or are otherwise part of, a memory cell 330a (illustrated using dotted lines) of the DRAM array 310. Similarly, the capacitor 102b and the transistor 302b form, or are otherwise part of, a memory cell 330b (illustrated using dotted lines) of the DRAM array 310. Although merely two memory cells 330a and 330b are illustrated in FIG. 3, the DRAM array 310 is likely to include several such memory cells.

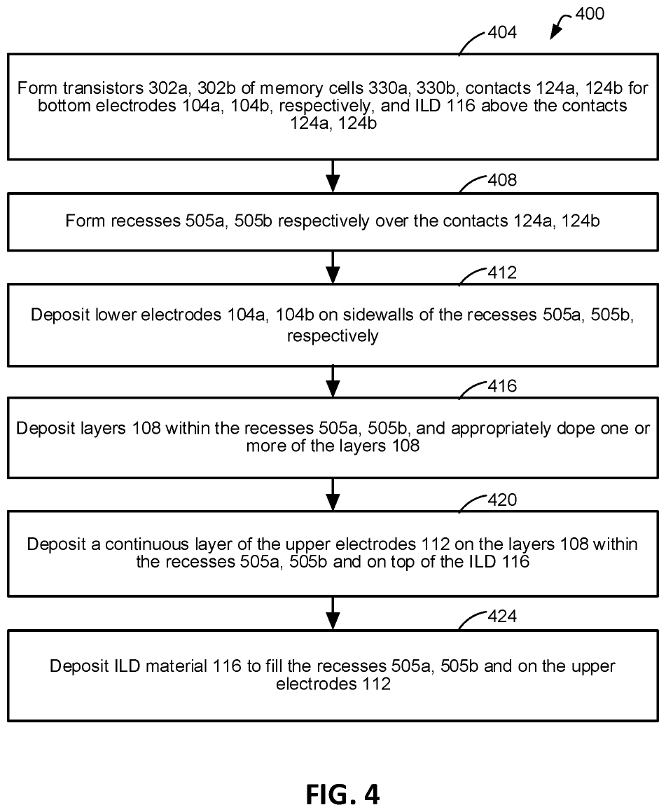

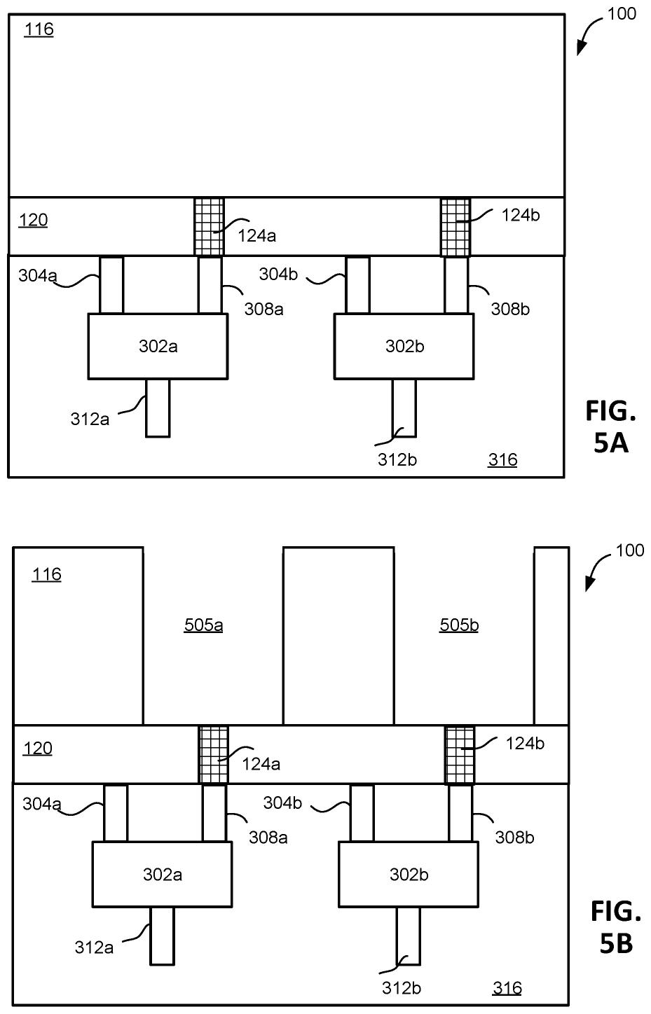

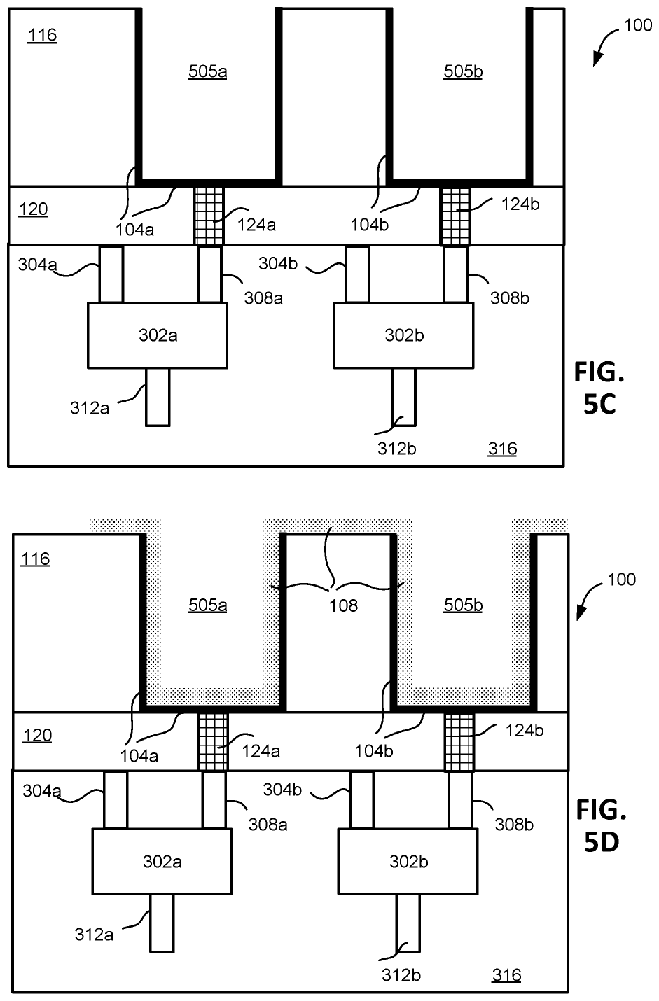

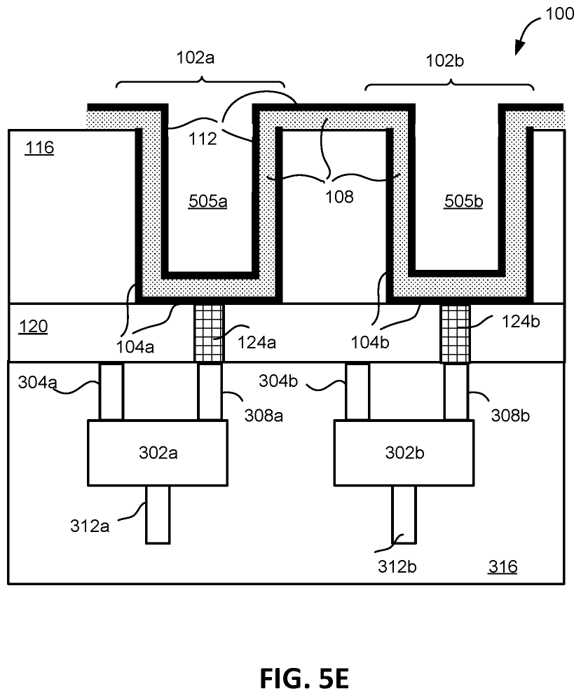

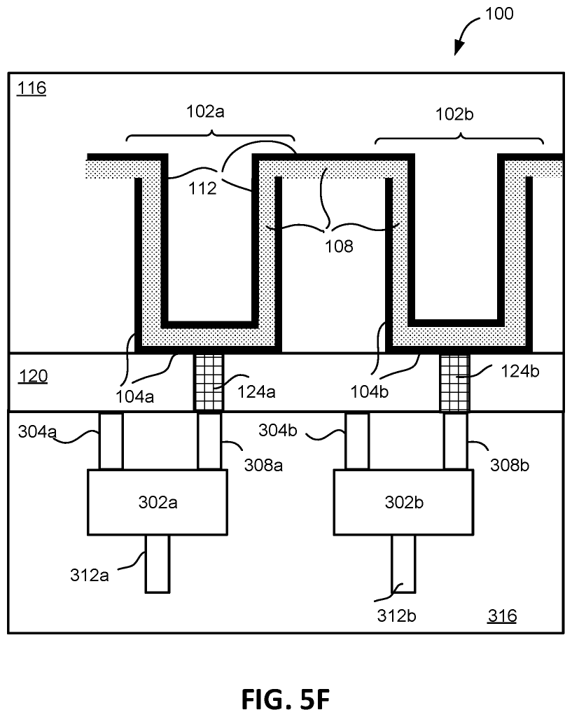

FIG. 4 illustrates a flowchart depicting a method 400 of forming an IC (such as the IC 100 of FIG. 3) comprising first and second MIM capacitors 102a, 102b respectively above corresponding first and second transistors 302a, 302b, where each of the first and second capacitors 102a, 102b comprise (i) a first electrode 104, (ii) a second electrode 112, and (iii) one or more intervening layers 108 between the first and second electrodes, wherein the one or more intervening layers 108 comprise at least a first layer comprising (a) a first metal, (b) oxygen, and (c) a second metal that is elementally different from the first metal and that is doped within the first layer, in accordance with an embodiment of the present disclosure. FIGS. 5A-5F illustrate cross-sectional views of an IC (such as the IC 100 of FIG. 1) in various stages of processing, in accordance with an embodiment of the present disclosure. FIGS. 4 and 5A-5F will be discussed in unison.

Referring to FIG. 4, the method 400 includes, at 404, forming transistors 302a, 302b of the memory cells 330a, 330b, contacts 124a, 124b for bottom electrodes 104a, 104b, respectively, of the capacitors 102a, 102b, and ILD 116 above the contacts 124a, 124b, as illustrated in FIG. 5A. The formation process at 404 may be performed any appropriate technique for formation of transistors, contacts, and deposition of the ILD material.

Referring again to FIG. 4, the method 400 then proceeds from 404 to 408, where recesses 505a, 505b respectively are formed over the contacts 124a, 124b, as illustrated in FIG. 5B. The recesses may be formed using an appropriate etching technique, such as anisotropic etching process. The capacitors 102a, 102b are to be respectively formed within the recesses 505a, 505b.

Referring again to FIG. 4, the method 400 then proceeds from 408 to 412, where the lower electrodes 104a, 104b are deposited (e.g., conformally deposited) within sidewalls of the recesses 505a, 505b, as illustrated in FIG. 5C. The lower electrodes 104a, 104b are conformally deposited using any suitable deposition technique, such as chemical vapor deposition (CVD), physical vapor deposition (PVD), atomic layer deposition (ALD), vapor-phase epitaxy (VPE), molecular beam epitaxy (MBE), liquid-phase epitaxy (LPE), or electroplating, for example.

Referring again to FIG. 4, the method 400 then proceeds from 412 to 416, where layers 108 are deposited (e.g., conformally deposited) within the recesses 505a, 505b, and where one or more of the layers 108 are appropriately doped, as discussed with respect to FIG. 1. FIG. 5D illustrates the layers 108 deposited within the recesses 505a, 505b, as well as on top of the ILD 116 between the two recesses 505a, 505b, e.g., similar to the configuration of the layers 108 in FIG. 1. However, in another example (and although not illustrated in FIG. 5D), the layers 108 on top of the ILD 116 between the two recesses 505a, 505b may not be deposited (or may be removed after deposition), e.g., similar to the configuration of the layers 108 in FIG. 2. Thus, a M-I (metal-insulator) thin film stack is now within the recesses 505a, 505b. The layers 108 are deposited using any suitable deposition technique, such as CVD, PVD, ALD, VPE, MBE, or LPE, for example. One or more of the layers 108 are doped using any suitable doping or implantation process.

Referring again to FIG. 4, the method 400 then proceeds from 416 to 420, where the upper electrodes 112 are deposited (e.g., conformally deposited) on the layers 108 within the recesses 505a, 505b and on top of the ILD 116, as illustrated in FIG. 5E. Thus, the upper electrodes 112 form a continuous layer within both the recesses 505a, 505b, as discussed with respect to FIG. 1 and as illustrated in FIGS. 1 and 5E. Thus, a M-I-M (metal-insulator-metal) thin film stack is now within the recesses 505a, 505b, to respectively form the MIM capacitors 102a, 102b within the recesses 505a, 505b. The upper electrodes layers 112 are deposited using any suitable deposition technique, such as CVD, PVD, ALD, VPE, MBE, LPE, or electroplating, for example.

Referring again to FIG. 4, the method 400 then proceeds from 420 to 424, where ILD material 116 is deposited to fill the recesses 505a, 505b and on the upper electrodes 112, as illustrated in FIG. 5F. The ILD material 116 is deposited using any suitable deposition technique, such as CVD, PVD, ALD, VPE, MBE, or LPE, for example. This completes the section of the IC 100 of FIG. 3.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

### Example System

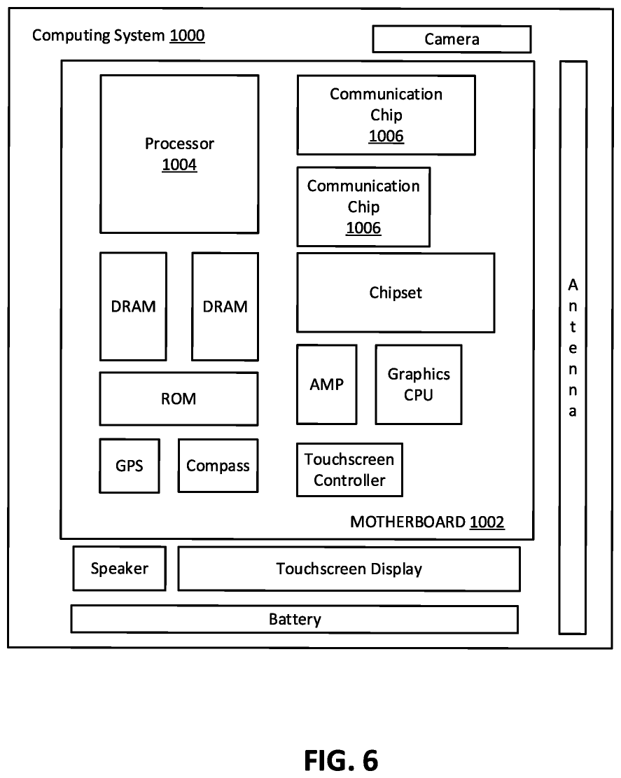

FIG. 6 illustrates a computing system 1000 implemented with integrated circuit structures having one or more memory cells formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit (IC) comprising: a transistor device; a first layer comprising electrically conductive material, the first layer conductively coupled to the transistor device; a second layer comprising electrically conductive material above the first layer; and one or more intervening layers between the first and second layers, the one or more intervening layers comprise at least a third layer, wherein the third layer comprise (i) a first metal, (ii) oxygen, and (iii) one or both of a second metal or an oxide thereof within the third layer.

Example 2. The integrated circuit of claim 1, wherein the concentration of the second metal or the oxide thereof in the third layer is in the range of 1E12 to 1E24 atoms per cubic cm.

Example 3. The integrated circuit of any one of examples 1-2, wherein the second metal is elementally different from the first metal.

Example 4. The integrated circuit of any one of examples 1-3, wherein the first metal comprises one of hafnium, aluminum, zirconium, titanium, or tantalum.

Example 5. The integrated circuit of any one of examples 1-4, wherein the second metal comprises one of hafnium, aluminum, zirconium, titanium, lanthanum, yttrium, gadolinium, or palladium.

Example 6. The integrated circuit of any one of examples 1-5, wherein each of the first and second layers comprise a metal or an alloy thereof.

Example 7. The integrated circuit of any one of examples 1-6, wherein the one or more intervening layers further comprise (i) a fourth layer comprising a third metal and oxygen, and (ii) a fifth layer comprising a fourth metal and oxygen, and wherein at least one of the fourth layer or the fifth layer is substantially undoped.

Example 8. The integrated circuit of example 7, wherein the third layer is between the fourth and fifth layers.

Example 9. The integrated circuit of example 8, wherein the third metal and the fourth metal are the same metal.

Example 10. The integrated circuit of any one of examples 7-9, wherein the fourth layer is between the third and fifth layers.

Example 11. The integrated circuit of example 10, wherein the first metal and the fourth metal are the same metal.

Example 12. The integrated circuit of any one of examples 1-11, wherein the first layer is conductively coupled to a drain of the transistor device.

Example 13. The integrated circuit of any one of examples 1-12, wherein the transistor device is below the first layer.

Example 14. The integrated circuit of any one of examples 1-13, wherein the first layer, the second layer, and the one or more intervening layers between the first and second layers form a metal-insulator-metal (MIM) capacitor.

Example 15. The integrated circuit of example 14, wherein the first layer and the second layer comprise a lower electrode and an upper electrode, respectively, of the MIM capacitor.

Example 16. The integrated circuit of any one of examples 14-15, wherein the MIM capacitor and the transistor device, in combination, form a memory cell of a dynamic random access memory (DRAM) array.

Example 17. The integrated circuit of any one of examples 1-16, wherein: the integrated circuit includes a first metal-insulator-metal (MIM) capacitor that comprises the first layer, the second layer, and the one or more intervening layers; the transistor device is a first transistor device, and the integrated circuit further comprises a second transistor device; and the integrated circuit includes a second MIM capacitor comprising a fourth layer comprising electrically conductive material, the fourth layer conductively coupled to the second transistor device, a fifth layer comprising electrically conductive material above the fourth layer, and one or more additional intervening layers between the fourth and fifth layers, the one or more additional intervening layers comprise at least a sixth layer, wherein the sixth layer comprise (i) a third metal, (ii) oxygen, and (iii) one or both of a fourth metal or an oxide thereof within the sixth layer, wherein the second layer is an upper electrode of the first MIM capacitor, the fifth layer is an upper electrode of the second MIM capacitor, and the second and fifth layers form a continuous upper electrode for both the first and second MIM capacitors.

Example 18. A memory array comprising: a memory cell comprising (i) a transistor, and (ii) a capacitor above and conductively coupled to the transistor, wherein the capacitor comprises a first electrode, a second electrode, and one or more layers of metal oxide between the first and second electrodes, wherein at least a first layer of the one or more layers of metal oxide comprises (i) an oxide of a first metal, and (ii) a second metal or an oxide thereof within the first layer.

Example 19. The memory array of example 18, wherein the memory cell is a dynamic random access memory (DRAM) cell.

Example 20. The memory array of any one of examples 18-19, wherein the memory cell is an embedded dynamic random access memory (eDRAM) cell.

Example 21. The memory array of any one of examples 18-20, wherein the second metal is elementally different from the first metal.

Example 22. The memory array of any one of examples 18-21, wherein the first layer is doped with the second metal or the oxide thereof with a doping concentration in the range of 1E12 to 1E24 atoms per cubic cm.

Example 23. The memory array of any one of examples 18-22, wherein the first metal comprises one of hafnium, aluminum, zirconium, titanium, or tantalum.

Example 24. The memory array of any one of examples 18-23, wherein the second metal comprises one of hafnium, aluminum, zirconium, titanium, lanthanum, yttrium, gadolinium, or palladium.

Example 25. The memory array of any one of examples 18-24, wherein the one or more layers of metal oxide further comprises a second layer that includes an oxide of a third metal.

Example 26. The memory array of any one of examples 18-25, wherein the one or more layers of metal oxide comprises a second layer that includes an oxide of a third metal, and wherein the second layer is substantially undoped.

Example 27. The memory array of example 25, wherein the third metal and the second metal are elementally the same.

Example 28. The memory array of example 26, wherein the one or more layers of metal oxide further comprises a third layer that includes an oxide of a fourth metal.

Example 29. The memory array of example 28, wherein the third layer is substantially undoped.

Example 30. The memory array of any one of examples 28-29, wherein the first layer is between the second and third layers.

Example 31. The memory array of any one of examples 28-30, wherein the second layer is between the first and third layers.

Example 32. A capacitor structure comprising: a first electrode comprising conductive material; a second electrode comprising conductive material; a first layer, a second layer, and a third layer between the first and second electrodes, wherein the first layer comprises an oxide of a first metal, the second layer comprise an oxide of a second metal, and the third layer comprises an oxide of a third metal, wherein at least one of the first, second, or third layers is doped with one or both of (i) a fourth metal or (ii) an oxide of the fourth metal, and wherein at least another of the first, second, or third layers is substantially undoped.

Example 33. The capacitor structure of example 32, wherein: the second layer is between the first and third layers; and the first and third metals are elementally the same, and the first and second metals are elementally different.

Example 34. The capacitor structure of any one of examples 32-33, wherein the first layer is doped with one or both of the fourth metal or the oxide of the fourth metal, and wherein the fourth metal is elementally different from the first metal.

Example 35. The capacitor structure of any one of examples 32-34, wherein each of the first metal, the second metal, and the third metal comprises a corresponding one of hafnium, aluminum, zirconium, titanium, or tantalum.

Example 36. The capacitor structure of any one of examples 32-35, wherein the fourth metal comprises one of hafnium, aluminum, zirconium, titanium, lanthanum, yttrium, gadolinium, or palladium.

Example 37. The capacitor structure of any one of examples 32-36, wherein the capacitor structure is above, and conductively coupled to, a drain terminal of a transistor.

Example 38. The capacitor structure of example 37, wherein the capacitor structure and the transistor form a memory cell of a dynamic random access memory (DRAM) array.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An integrated circuit (IC) comprising:
a transistor device;
a first layer comprising electrically conductive material, the first layer conductively coupled to the transistor device;
a second layer comprising electrically conductive material above the first layer; and
one or more intervening layers between the first and second layers, the one or more intervening layers comprise at least a third layer, wherein the third layer comprise (i) a first metal, (ii) oxygen, and (iii) one or both of a second metal or an oxide thereof within the third layer.

2. The integrated circuit of claim 1, wherein the concentration of the second metal or the oxide thereof in the third layer is in the range of 1E12 to 1E24 atoms per cubic cm.

3. The integrated circuit of claim 1, wherein the second metal is elementally different from the first metal.

4. The integrated circuit of claim 1, wherein the first metal comprises one of hafnium, aluminum, zirconium, titanium, or tantalum.

5. The integrated circuit of claim 1, wherein the second metal comprises one of hafnium, aluminum, zirconium, titanium, lanthanum, yttrium, gadolinium, or palladium.

6. The integrated circuit of claim 1, wherein each of the first and second layers comprise a metal or an alloy thereof.

7. The integrated circuit of claim 1, wherein the one or more intervening layers further comprise (i) a fourth layer comprising a third metal and oxygen, and (ii) a fifth layer comprising a fourth metal and oxygen, and wherein at least one of the fourth layer or the fifth layer is substantially undoped.

8. The integrated circuit of claim 7, wherein the third layer is between the fourth and fifth layers.

9. The integrated circuit of claim 8, wherein the third metal and the fourth metal are the same metal.

10. The integrated circuit of claim 7, wherein the fourth layer is between the third and fifth layers.

11. The integrated circuit of claim 10, wherein the first metal and the fourth metal are the same metal.

12. The integrated circuit of claim 1, wherein the first layer is conductively coupled to a drain of the transistor device.

13. The integrated circuit of claim 1, wherein the first layer, the second layer, and the one or more intervening layers between the first and second layers form a metal-insulator-metal (MIM) capacitor.

14. The integrated circuit of claim 1, wherein:
the integrated circuit includes a first metal-insulator-metal (MIM) capacitor that comprises the first layer, the second layer, and the one or more intervening layers;
the transistor device is a first transistor device, and the integrated circuit further comprises a second transistor device; and
the integrated circuit includes a second MIM capacitor comprising
a fourth layer comprising electrically conductive material, the fourth layer conductively coupled to the second transistor device,
a fifth layer comprising electrically conductive material above the fourth layer, and
one or more additional intervening layers between the fourth and fifth layers, the one or more additional intervening layers comprise at least a sixth layer, wherein the sixth layer comprise (i) a third metal, (ii) oxygen, and (iii) one or both of a fourth metal or an oxide thereof within the sixth layer,
wherein the second layer is an upper electrode of the first MIM capacitor, the fifth layer is an upper electrode of the second MIM capacitor, and the second and fifth layers form a continuous upper electrode for both the first and second MIM capacitors.

15. A memory array comprising:
a memory cell comprising (i) a transistor, and (ii) a capacitor above and conductively coupled to the transistor,
wherein the capacitor comprises
a first electrode,
a second electrode, and
one or more layers of metal oxide between the first and second electrodes, wherein at least a first layer of the one or more layers of metal oxide comprises (i) an oxide of a first metal, and (ii) a second metal or an oxide thereof within the first layer.

16. The memory array of claim 15, wherein the memory cell is an embedded dynamic random access memory (eDRAM) cell.

17. The memory array of claim 15, wherein the one or more layers of metal oxide comprises a second layer that includes an oxide of a third metal, and wherein the second layer is substantially undoped.

18. A capacitor structure comprising:
a first electrode comprising conductive material;
a second electrode comprising conductive material;
a first layer, a second layer, and a third layer between the first and second electrodes,
wherein the first layer comprises an oxide of a first metal, the second layer comprise an oxide of a second metal, and the third layer comprises an oxide of a third metal,
wherein at least one of the first, second, or third layers is doped with one or both of (i) a fourth metal or (ii) an oxide of the fourth metal, and
wherein at least another of the first, second, or third layers is substantially undoped.

19. The capacitor structure of claim 18, wherein the first layer is doped with one or both of the fourth metal or the oxide of the fourth metal, and wherein the fourth metal is elementally different from the first metal.

20. The capacitor structure of claim 18, wherein the capacitor structure is above, and conductively coupled to, a drain terminal of a transistor.
